(19) United States
(12) Patent Application Publication
(10) Pub. No.: US 2026/0182265 A1
(43) Pub. Date: Jun. 25, 2026

(54) LARGE-AREA SEMICONDUCTOR DEVICE REALIZED THROUGH A SINGLE DOMAIN AND METHOD OF MANUFACTURING THE SAME

(71) Applicant: Myongji University Industry and Academia Cooperation Foundation, Yongin-si (KR)

(72) Inventors: Min Woo KIM, Hwaseong-si (KR); Nu Ri KIM, Yongin-si (KR); Se Won YOON, Incheon (KR)

(21) Appl. No.: 19/181,289

(22) Filed: Apr. 16, 2025

(30) Foreign Application Priority Data
Dec. 19, 2024 (KR) 10-2024-0191221

(51) Int. Cl. H01L 21/02; H01L 21/033; H10D 62/80

(52) U.S. Cl. CPC H10P 14/3436; H10D 62/883; H10P 14/271; H10P 14/2905; H10P 14/3238; H10P 76/405

(57) ABSTRACT

A large-area semiconductor device through a single domain and a method of manufacturing the same are disclosed. The method comprises forming an absorption layer on a substrate, forming first sub semiconductor characteristic material layers on the absorption layer in spaces among first sub masks by using a first mask including the first sub masks, forming a second mask including second sub masks on the first sub semiconductor characteristic material layers and forming second sub semiconductor characteristic material layers in spaces among the second sub masks. Here, a large-area semiconductor characteristic material layer is formed on the absorption layer by the first sub semiconductor characteristic material layers and the second sub semiconductor characteristic material layers.

### CROSS-REFERENCE TO RELATED APPLICATIONS

This application claims priority from and the benefit of Korean Patent Application 10-2024-0191221, filed with the Korean Intellectual Property Office on Dec. 19, 2024, the disclosure of which is hereby incorporated by reference in its entirety.

### TECHNICAL FIELD

The disclosure relates to a large-area semiconductor device realized through a single domain and a method of manufacturing the same.

### BACKGROUND ART

A precursor growth is utilized to manufacture semiconductor devices. However, a quality of the semiconductor device is degraded due to non-uniform growth.

Additionally, nucleation occurred randomly, leading to the issue of precursor growth being confined to specific regions. Due to these factors, it was not possible to fabricate a semiconductor device with a large-area single layer.

### SUMMARY

The disclosure is to provide a large-area semiconductor device through a single domain and a method of manufacturing the same.

A method of manufacturing a semiconductor device according to an embodiment of the disclosure includes forming an absorption layer on a substrate; forming first sub semiconductor characteristic material layers on the absorption layer in spaces among first sub masks by using a first mask including the first sub masks; forming a second mask including second sub masks on the first sub semiconductor characteristic material layers; and forming second sub semiconductor characteristic material layers in spaces among the second sub masks. Here, a large-area semiconductor characteristic material layer is formed on the absorption layer by the first sub semiconductor characteristic material layers and the second sub semiconductor characteristic material layers.

A semiconductor device according to an embodiment of the disclosure includes a substrate; an absorption layer formed on the substrate; and a semiconductor characteristic material layer formed on the absorption layer. Here, semiconductor characteristic material of the semiconductor characteristic material layer is −0.2 eV/Å2 or less.

A semiconductor device according to another embodiment of the disclosure includes a substrate; an absorption layer formed on the substrate; and a semiconductor characteristic material layer formed on the absorption layer. Here, wherein the semiconductor characteristic material layer is formed by disposing sequentially sub semiconductor characteristic material layers on the absorption layer, and each of the sub semiconductor characteristic material layers has triangular shape.

A semiconductor device according to still another embodiment of the disclosure includes a substrate; an absorption layer formed on the substrate; and a semiconductor characteristic material layer formed on the absorption layer. Here, the semiconductor characteristic material layer is formed by disposing sequentially sub semiconductor characteristic material layers on the absorption layer, and each of the sub semiconductor characteristic material layers is formed by growing one precursor.

A method of manufacturing a semiconductor device of the disclosure forms a semiconductor characteristic material layer through a single domain, thereby realizing large-area expansion while maintaining an initial domain to form a large-area single layer.

Additionally, the method of manufacturing the semiconductor device achieves uniform-growth through limitation of a growth region, and thus characteristics of the semiconductor characteristic material layer may be enhanced.

Furthermore, the method of manufacturing the semiconductor device controls selectively the growth of the precursor by using a hard mask, thereby controlling precisely a location of nucleation in large-area growth.

### BRIEF DESCRIPTION OF DRAWINGS

Example embodiments of the present disclosure will become more apparent by describing in detail example embodiments of the present disclosure with reference to the accompanying drawings, in which:

FIG. 1 is a view illustrating a process of manufacturing a semiconductor device according to an embodiment of the disclosure; and

FIG. 2 is a view illustrating a depositing process of Molybdenum disulfide MoS₂ according to an embodiment of the disclosure.

### DETAILED DESCRIPTION

In the present specification, an expression used in the singular encompasses the expression of the plural, unless it has a clearly different meaning in the context. In the present specification, terms such as “comprising” or “including,” etc., should not be interpreted as meaning that all of the elements or operations are necessarily included. That is, some of the elements or operations may not be included, while other additional elements or operations may be further included. Also, terms such as “unit,” “module,” etc., as used in the present specification may refer to a part for processing at least one function or action and may be implemented as hardware, software, or a combination of hardware and software.

The disclosure relates to a semiconductor device and a method of manufacturing the same, and it may form a large-area single layer by realizing a single domain through limitation of a growth region. The limitation of the growth region may induce uniform-growth. Here, the semiconductor device is embodied with semiconductor characteristic material and is not limited as a specific device. The semiconductor device may be employed in an FET, a sensor, an optic detector and so on.

The semiconductor characteristic material is material in-between electrical conductivity of a conductor and an insulator and its conductivity increases according as temperature goes up. For example, a Molybdenum disulfide MoS₂ with a 2D hexagonal system or Tungsten Diselenide WSe₂ may be utilized as the semiconductor characteristic material used in the method of manufacturing the semiconductor device of the disclosure.

In an embodiment, the Molybdenum disulfide MoS₂ may be used for manufacturing an N-type semiconductor device and the Tungsten Diselenide WSe₂ may be used for manufacturing a P-type semiconductor device.

Hereinafter, various embodiments of the disclosure will be described in detail with reference to accompanying drawings. It will be assumed that the semiconductor characteristic material is the Molybdenum disulfide MoS₂, for convenience of description.

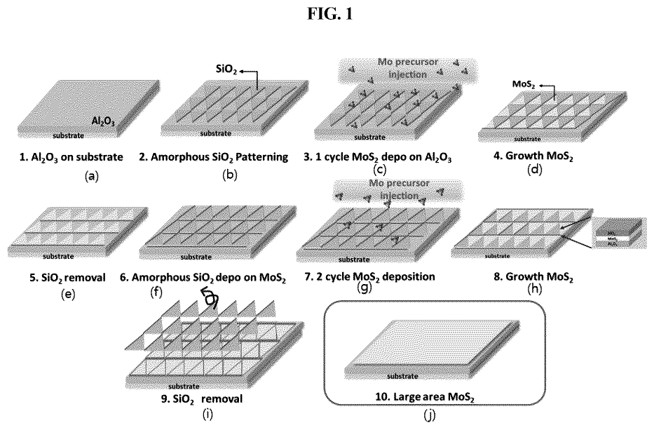

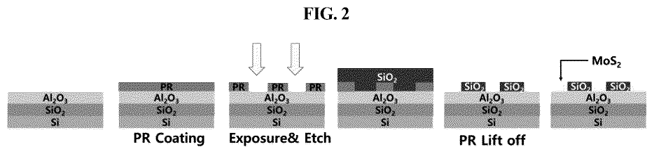

FIG. 1 is a view illustrating a process of manufacturing a semiconductor device according to an embodiment of the disclosure, and FIG. 2 is a view illustrating a depositing process of Molybdenum disulfide MoS₂ according to an embodiment of the disclosure.

As shown in (a) in FIG. 1, a method of manufacturing a semiconductor device of the present embodiment may form an absorption layer (insulating layer), e.g. single crystal aluminum oxide (sapphire) Al₂O₃ layer on a substrate. This structure may be referred to as a sapphire substrate. Here, silicon Si and silicon dioxide SiO₂ may be sequentially formed in the substrate. That is, the substrate may be a silicon substrate but it is not limited as the silicon substrate.

The aluminum oxide Al₂O₃ has high bond energy (approximately −0.2 eV/Å2˜−0.4 eV/Å2) with the Molybdenum disulfide MoS₂, and so Molybdenum disulfide MoS₂ precursor is strongly absorbed to a surface of the absorption layer. As a result, initial nucleation may be rapidly formed and uniform domain may be achieved because the Molybdenum disulfide MoS₂ precursor is stably absorbed to the surface of the absorption layer. In this case, the difference of lattice constant of the aluminum oxide Al₂O₃ and the Molybdenum disulfide MoS₂ is approximately 2.7%, and thus it is possible to realize epitaxial growth.

In another embodiment, the absorption layer may be formed of amorphous Hafnium Dioxide HfO₂. The Hafnium Dioxide HfO₂ has high bond energy (approximately −0.3 eV/Å2˜−0.5 eV/Å2) with the Molybdenum disulfide MoS₂, and so the Molybdenum disulfide MoS₂ precursor is strongly absorbed to a surface of the absorption layer. As a result, initial nucleation may be rapidly formed and uniform domain may be achieved because the Molybdenum disulfide MoS₂ precursor is stably absorbed to the surface of the absorption layer. In this case, the difference of lattice constant of the Hafnium Dioxide HfO₂ and the Molybdenum disulfide MoS₂ is approximately 3.1%, and thus it is possible to realize epitaxial growth.

Subsequently, the method of manufacturing the semiconductor device may form a first mask, e.g. Silicon Dioxide SiO₂ on the absorption layer as shown in (b) in FIG. 1.

The Silicon Dioxide SiO₂ has an amorphous structure and its surface energy is 0.9 J/m². Additionally, an absorption rate with the Molybdenum disulfide MoS₂ precursor is lower compared to the aluminum oxide Al₂O₃ and the Hafnium Dioxide HfO₂ and the bond energy (approximately −0.1 eV/Å2˜−0.2 eV/Å2) between the Molybdenum disulfide MoS₂ and the Silicon Dioxide SiO₂ is low. As a result, the absorption of the Molybdenum disulfide MoS₂ precursor and the nucleation are suppressed on the surface of the first mask. That is, the first mask may function as a physical barrier and the growth of the Molybdenum disulfide MoS₂ may be controlled by using the first mask.

In an embodiment, the first mask may include first sub masks disposed sequentially with a triangular shape, and thus spaces may be formed among the first sub masks, the Molybdenum disulfide MoS₂ precursor growing in the spaces. Here, the triangular shape may be an equilateral triangle, and a side of the triangle may have a length of 100 nm to 1 μm to limit a growth region of the precursor. Furthermore, the space may have a triangular shape.

The first sub masks disposed sequentially with the triangular shape may be connected in multistage as shown in (b) in FIG. 1. For example, triangles in an upper region may be sequentially formed in an x-axis direction while their parts are contacted one another, triangles in a middle region may be sequentially formed in an x-axis direction while their parts are contacted one another and triangles in a lower region may be sequentially formed in an x-axis direction while their parts are contacted one another. In this case, apexes of the triangles in the upper part may be contacted with points at which the triangles in the middle region meet, and apexes of the triangles in the middle region may be contacted with points at which the triangles in the lower region meet. As a result, the spaces with a triangular shape where the Molybdenum disulfide MoS₂ precursor grows may be formed. However, a shape and an array of the first sub masks may be variously modified as long as the space with triangular shape is formed.

On the other hand, the first sub mask may have different shape such as a rectangular shape, etc. However, it is not easy to form a single domain where one precursor locates in one space when the first sub mask has the different shape. Accordingly, it is preferable that the first sub mask has the triangular shape with considerably small area.

In an embodiment, the first sub masks may have a size such that the single domain is formed through limitation of the growth region of the precursor. That is, each of the first sub masks may have a size such that one precursor is disposed in each of the spaces between the first sub masks. For example, the first sub mask may have the triangular shape and one side of the triangle shape may have a length of 100 nm to 1 μm.

The first sub masks may be manufactured in hard mask type or formed through a trench type etching.

Subsequently, the method of manufacturing the semiconductor device may deposit the Molybdenum disulfide MoS₂ precursor on a structure in which the absorption layer and the first mask is sequentially disposed on the substrate, as shown in (c) in FIG. 1. Here, the depositing may be performed through various methods such as a Chemical Vapor Deposition CVD, a Physical Vapor Decomposition PVD, an Atomic Layer Deposition ALD, etc., and it is not limited as a specific depositing method.

In an embodiment, the method of manufacturing the semiconductor device may coat a photoresist on the absorption layer, expose the coated photoresist, deposit silicon dioxide SiO₂ on the exposed structure, form the spaces by removing the photoresist from the deposited structure and deposit the Molybdenum disulfide MoS₂ precursor in the spaces.

Next, the method of manufacturing the semiconductor device may form sub MoS₂ layers in the spaces among the first sub masks by growing the Molybdenum disulfide MoS₂ precursor as shown in (d) in FIG. 1. In this case, the sub MoS₂ layer may not be formed on the first mask because bond energy between the first mask and the Molybdenum disulfide MoS₂ is low.

Subsequently, the method of manufacturing the semiconductor device may remove the first mask as shown in (e) in FIG. 1. As a result, only sub MoS₂ layers with the triangular shape may exist on the absorption layer. In the step, the sub MoS₂ layer is not formed in the spaces corresponding to the first mask.

Next, the method of manufacturing the semiconductor device may form a second mask on the sub MoS₂ layers as shown in (f) in FIG. 1. As a result, second sub masks formed of for example Silicon Dioxide SiO₂ may be formed on the sub MoS₂ layers with the triangular shape. Accordingly, spaces with triangular shape may be formed between the second sub masks. Here, the second sub masks may cover perfectly the sub MoS₂ layers.

Subsequently, the method of manufacturing the semiconductor device may deposit a Molybdenum disulfide MoS₂ precursor on a structure where the absorption layer, the sub MoS₂ layers and the second mask are sequentially formed as shown in (g) in FIG. 1.

Next, the method of manufacturing the semiconductor device may form sub MoS₂ layer in spaces among the second sub masks by growing the Molybdenum disulfide MoS₂ precursor in the spaces as shown in (h) in FIG. 1.

Subsequently, the method of manufacturing the semiconductor device may remove the second mask as shown in (i) in FIG. 1. As a result, a large-area MoS₂ layer including MoS₂ layers may be formed on the absorption layer as shown in (j) in FIG. 1.

Briefly, the method of manufacturing the semiconductor device may form the absorption layer having high bond energy with the Molybdenum disulfide MoS₂ on the substrate, form partially the sub MoS₂ layer by using the first mask having low bond energy with the Molybdenum disulfide MoS₂ and form the sub MoS₂ layers in the other parts by using the second mask having low bond energy with the Molybdenum disulfide MoS₂, thereby form the large-area MoS₂ layer.

In above description, the first mask and the second mask are formed of the same material. However, the first mask and the second mask may be formed of different material as long as the different material has low bond energy with the Molybdenum disulfide MoS₂.

In semiconductor device, the absorption layer may be formed on the substrate, and the large-area semiconductor characteristic material layer, e.g MoS₂ layer formed of for example Molybdenum disulfide MoS2 may be formed on the absorption layer. In this case, the semiconductor characteristic material layer may be achieved through the single domain. Of course, additional layer may be formed on the semiconductor characteristic material layer according to desired semiconductor device.

In an embodiment, the semiconductor device may include the absorption layer having bond energy of −0.2 eV/Å2 or less with the semiconductor characteristic material and the semiconductor characteristic material layer formed of the semiconductor characteristic material on the substrate. Here, the semiconductor characteristic material may be the Molybdenum disulfide MoS₂ or the Tungsten Diselenide WSe₂. Furthermore, the semiconductor characteristic material layer may be formed through the growth of the precursor.

In an embodiment, in the semiconductor device, sub semiconductor characteristic material layers with triangular shape may be sequentially disposed on the substrate on which the absorption layer is formed to realize one large-area semiconductor characteristic material layer. Here, the triangular shape may be an equilateral triangle and one side of the triangle may have a length of 100 nm to 1 μm. Moreover, each of the sub semiconductor characteristic material layers may be the single domain grown from one precursor.

Components in the embodiments described above can be easily understood from the perspective of processes. That is, each component can also be understood as an individual process. Likewise, processes in the embodiments described above can be easily understood from the perspective of components.

The embodiments of the disclosure described above are disclosed only for illustrative purposes. A person having ordinary skill in the art would be able to make various modifications, alterations, and additions without departing from the spirit and scope of the disclosure, but it is to be appreciated that such modifications, alterations, and additions are encompassed by the scope of claims set forth below.

1. A method of manufacturing a semiconductor device, the method comprising:
forming an absorption layer on a substrate;
forming first sub semiconductor characteristic material layers on the absorption layer in spaces among first sub masks by using a first mask including the first sub masks;
forming a second mask including second sub masks on the first sub semiconductor characteristic material layers; and
forming second sub semiconductor characteristic material layers in spaces among the second sub masks,
wherein a large-area semiconductor characteristic material layer is formed on the absorption layer by the first sub semiconductor characteristic material layers and the second sub semiconductor characteristic material layers.

2. The method of claim 1, wherein the absorption layer is formed of single crystal aluminum oxide Al₂O₃ or amorphous Hafnium Dioxide HfO₂, each of the sub masks is formed of Silicon Dioxide SiO₂, and each of the sub semiconductor characteristic material layers is formed of Molybdenum disulfide MoS₂ or Tungsten Diselenide WSe₂.

3. The method of claim 1, wherein bond energy between semiconductor characteristic material of the sub semiconductor characteristic material layers and material of the absorption layer is −0.2 eV/Å2 or less.

4. The method of claim 1, wherein the first sub masks are partially contacted one another while the first sub masks have triangular shape, the spaces formed by the first sub masks have triangular shape, the second sub masks are partially contacted one another while the second sub masks have triangular shape, and the spaces formed by the second sub masks have triangular shape,
and wherein the first sub masks, the spaces and the second sub masks be equilateral triangles, and one side of the equilateral triangle has a length of 100 nm to 1 μm.

5. The method of claim 1, wherein only one precursor is grown in each of the spaces formed by the first sub masks and the spaces formed by the second sub masks.

6. The method of claim 5, wherein the forming the first sub semiconductor characteristic material layers includes:
forming the first sub masks disposed sequentially with triangular shape on the absorption layer;
depositing a semiconductor characteristic material precursor on a structure where the first sub masks are formed;
forming the first sub semiconductor characteristic material layers by growing the semiconductor characteristic material precursor in the spaces formed by the first sub masks; and
removing the first sub masks.

7. The method of claim 5, wherein the forming the second sub semiconductor characteristic material layers includes:
depositing a semiconductor characteristic material precursor on a structure where the second sub masks are formed;
forming the second sub semiconductor characteristic material layers by growing the semiconductor characteristic material precursor in the spaces formed by the second sub masks; and
removing the second sub masks.

8. A semiconductor device comprising:
a substrate;
an absorption layer formed on the substrate; and
a semiconductor characteristic material layer formed on the absorption layer,
wherein bond energy between material of the absorption layer and semiconductor characteristic material of the semiconductor characteristic material layer is −0.2 eV/Å2 or less.

9. The semiconductor device of claim 8, wherein the substrate is a silicon substrate, the absorption layer is formed of single crystal aluminum oxide Al₂O₃ or amorphous Hafnium Dioxide HfO₂, and the semiconductor characteristic material layer is formed of Molybdenum disulfide MoS₂ or Tungsten Diselenide WSe₂.

10. The semiconductor device of claim 8, wherein the bond energy between the material of the absorption layer and the semiconductor characteristic material of the semiconductor characteristic material layer is −0.2 eV/Å2 to −0.5 eV/Å2.

11. A semiconductor device comprising:
a substrate;
an absorption layer formed on the substrate; and
a semiconductor characteristic material layer formed on the absorption layer,
wherein the semiconductor characteristic material layer is formed by disposing sequentially sub semiconductor characteristic material layers on the absorption layer, and
each of the sub semiconductor characteristic material layers has triangular shape.

12. The semiconductor device of claim 11, wherein the triangular shape is an equilateral triangle, and one side of the equilateral triangle has a length of 100 nm to 1 μm.

13. The semiconductor device of claim 11, wherein the substrate is a silicon substrate, the absorption layer is formed of single crystal aluminum oxide Al₂O₃ or amorphous Hafnium Dioxide HfO₂, and the semiconductor characteristic material layer is formed of Molybdenum disulfide MoS₂ or Tungsten Diselenide WSe₂.

14. The semiconductor device of claim 11, wherein each of the sub semiconductor characteristic material layers is triangles, and
a part of the sub semiconductor characteristic material layers is disposed in a reverse direction.

15. A semiconductor device comprising:
a substrate;
an absorption layer formed on the substrate; and
a semiconductor characteristic material layer formed on the absorption layer,
wherein the semiconductor characteristic material layer is formed by disposing sequentially sub semiconductor characteristic material layers on the absorption layer, and each of the sub semiconductor characteristic material layers is formed by growing one precursor.

16. The semiconductor device of claim 15, wherein the absorption layer is formed of single crystal aluminum oxide Al₂O₃ or amorphous Hafnium Dioxide HfO₂, and the semiconductor characteristic material layer is formed of Molybdenum disulfide MoS₂ or Tungsten Diselenide WSe₂.
